(19) United States
(12) Patent Application Publication
(10) Pub. No.: US 2016/0087023 A1
(43) Pub. Date: Mar. 24, 2016

(54) DISPLAY DEVICE AND MANUFACTURING METHOD THEREOF, AND AN INSPECTION METHOD OF A DISPLAY DEVICE

(71) Applicant: Japan Display Inc., Tokyo (JP)

(72) Inventor: Norihisa MAEDA, Tokyo (JP)

(21) Appl. No.: 14/856,240

(22) Filed: Sep. 16, 2015

(30) Foreign Application Priority Data
Sep. 22, 2014 (JP) 2014-192565

(51) Int. Cl. H01L 27/32; H01L 21/66; H01L 51/44

(52) U.S. Cl. CPC H01L 27/3276; H01L 51/442; H01L 22/32; H01L 22/14; H01L 2227/323

(57) ABSTRACT

A display device including a pixel region provided with a plurality of pixels, and a terminal region provided on an outer side of the pixel region, each of the plurality of pixels including a first electrode, an organic layer including a light emitting layer above the first electrode, and a second electrode having a transparency above the organic layer, the terminal region including a first wiring layer and a second wiring layer above the first wiring layer, and the first electrode and the second wiring layer having a same laminated structure.

### CROSS REFERENCE TO RELATED APPLICATIONS

This application is based upon and claims the benefit of priority from the prior Japanese Patent Application No. 2014-192565, filed on Sep. 22, 2014, the entire contents of which are incorporated herein by reference.

### FIELD

The present invention is related to a display device formed using a light emitting element and one disclosed embodiment of the invention is related to a structure of a panel provided with a light emitting element.

### BACKGROUND

Display devices are being developed provided with an organic electroluminescence element (referred to below as “organic EL element”) which is a type of light emitting element, in each pixel, and the light emitted from each pixel is controlled by a pixel circuit using a thin film transistor.

An organic EL element includes a structure in which an organic electroluminescence layer (referred to below as “organic EL layer”) formed from an organic electroluminescence material (referred to below as “organic EL material”) is sandwiched by a pair of electrode called an anode and cathode. Although it is possible the organic EL element to output light from both the anode and the cathode, it is possible to set the direction in which light is output by setting one of the electrodes as a reflecting electrode and the other electrode as a transparent electrode. A display device which uses an organic EL element is divided into a top emission type and a bottom emission type by the direction in which light is output by the organic EL element which forms a pixel. That is, a structure in which light is output upwards from the organic EL element is called a top emission type and a structure in which light is output is a downwards direction (side on which a thin film transistor is provided) of an organic EL element is called a bottom emission type.

In order to drive such a display device, it is necessary to input a video signal from a video signal source, a connection terminal is necessary for applying power for drive a circuit and to emit light from the organic EL element. The connection terminal is provided on one end of a substrate using a conductive film formed above the substrate when forming a pixel circuit or organic EL element.

Since is desirable that the connection terminal be a low resistance, although usually it is considered the be preferable to form the connection terminal using the same aluminum (Al) material as a wiring material of a pixel circuit, since the connection terminal is the part which is exposed to air, it is necessary to prevent an increase in contact resistance due to surface oxidation or corrosion of the aluminum (Al). For example, a structure is disclosed in Japanese Laid Open Patent No. 2001-282136 in which a high melting point metal layer such as titanium (Ti), an ITO layer (indium tin oxide) and an alloy layer of magnesium (Mg) and indium (In) are stacked above a terminal formed mainly from aluminum (Al) as the connection terminal of the display device. In addition, a structure is disclosed in Japanese Laid Open Patent No. 2004-158442 in which a first conductive layer formed mainly from Al or an Al alloy, and a cap layer formed mainly of a nickel (Ni) molybdenum (Mo) alloy is provided above the first conductive layer as another form of the connection terminal.

### SUMMARY

According to one embodiment of the present invention, a display device including a pixel region provided with a plurality of pixels, and a terminal region provided on an outer side of the pixel region, each of the plurality of pixels including a first electrode, an organic layer including a light emitting layer above the first electrode, and a second electrode having a transparency above the organic layer, the terminal region including a first wiring layer and a second wiring layer above the first wiring layer, and the first electrode and the second wiring layer having a same laminated structure.

According to one embodiment of the present invention, a manufacturing method of a display device including a pixel region provided with a plurality of pixels, and a terminal region provided on an outer side of the pixel region, the method including forming a first electrode including a light reflecting surface, an organic layer including a light emitting layer above the first electrode, and a second electrode having a transparency above the organic layer in the display region, forming a first wiring layer and second wiring layer above the first wiring layer in the terminal region, and forming the first electrode and the second wiring layer simultaneously.

According to one embodiment of the present invention, an inspection method of a display device including a pixel region provided with a plurality of pixels, and a terminal region provided on an outer side of the pixel region, the method including each of the plurality of pixels including a first electrode, an organic layer including a light emitting layer provided above the first electrode, and a second electrode having a transparency above the organic layer, the terminal region including a first wiring layer and a second wiring layer above the first wiring layer, the first electrode and the second wiring layer having a same laminated structure, and an inspection of the first electrode is performed using a film thickness of the second wiring layer as an alternative characteristic.

### BRIEF DESCRIPTION OF THE DRAWINGS

FIG. 1 is a perspective view diagram showing a structure of a display device related to one embodiment of the present invention;

FIG. 2 is planar view diagram showing a structure of a display device related to one embodiment of the present invention;

FIG. 3 is a cross-sectional diagram of a structure of a pixel region and terminal region of a display device related to one embodiment of the present invention;

FIG. 4A is a display device related to one embodiment of the present invention and shows a planar view of a terminal region;

FIG. 4B is a display device related to one embodiment of the present invention and shows a cross-sectional view of a terminal region;

FIG. 5A is a display device related to one embodiment of the present invention and shows a cross-sectional view of a pixel;

FIG. 5B is a display device related to one embodiment of the present invention and shows a cross-sectional view of a connection terminal;

FIG. 6A is a cross-sectional view for explaining a manufacturing method of a display device related to one embodiment of the present invention and shows a step for forming a source/drain electrode and first conductive layer extending to a terminal region;

FIG. 6B is a cross-sectional view for explaining a manufacturing method of a display device related to one embodiment of the present invention and shows a step for forming a second insulation layer and third insulation layer;

FIG. 7A is a cross-sectional view for explaining a manufacturing method of a display device related to one embodiment of the present invention and shows a step for forming a contact hole of a pixel region and an aperture of a terminal region; and

FIG. 7B is a cross-sectional view for explaining a manufacturing method of a display device related to one embodiment of the present invention and shows a step for forming a first electrode of a pixel and a second wiring layer of a connection terminal.

### DESCRIPTION OF EMBODIMENTS

The embodiments of the present invention are explained below while referring to the diagrams. However, the present invention can be realized using many different forms and should not be interpreted as being limited to the details described in the embodiments exemplified below. In order to better clarify explanation, each width, thickness and shape are sometimes shown schematically in the diagrams compared to actual components and are only examples and should not limit an interpretation of the present invention. In addition, in the specification and each diagram, the same reference symbols are attached to elements that have appeared previously in the diagrams and a detailed explanation is sometimes omitted where appropriate.

In the specification, as long as there is no particular exception, in the case where certain parts or regions are [above (or below)] other parts or regions, this includes being directly above [or directly below] other parts or regions as well as being upwards (or downwards) of other parts or regions, that is, other structural elements may also be included upwards (or downwards) of other parts or regions with a space there between.

In many cases, an organic EL element provided in a display device includes a structure in which an anode, an organic EL layer and cathode are stacked. The organic EL element is provided over an insulation layer, and a thin film transistor which forms a pixel circuit is buried with that insulation layer. In a top emission type display device, a structure (for example, ITO/Ag/ITO) is used in which a metal layer having light reflection properties such as aluminum (Al) or silver (Ag), and a transparent conductive layer such as ITO are stacked in order to an anode to a light reflective electrode. Here, since a transparent conductive layer provided on an upper side (organic EL layer side) of a metal layer is related to optical design, film thickness control becomes important. When the film thickness of the transparent conductive layer is varied within a manufacturing lot or between manufacturing lots, since the strength and tone of the light emitted from a pixel becomes varied, film thickness control is important not only at the manufacturing stage but also in the finished product in order to maintain product quality.

However, since an organic EL element provided in a pixel is sealed using a sealing member, in order to know the thickness of a transparent conductive layer provided in an anode after completion of a display panel, it is necessary to either (1) analyze the panel, remove the cathode and organic EL layer and set the film thickness using an ellipsometer while the anode is exposed or (2) analyze the panel, observe a cross-sectional structure of the panel using a transmission electron microscope and evaluate the film thickness of the transparent conductive layer of the anode or (3) arrange a region for a test sample in advance in a part of a mother glass.

The methods (1) and (2) described above are damage inspections and it is necessary to break a display panel. Not only does this lead to a water of a completed product but also the work required to evaluate film thickness becomes complex and the number of processes are increased. In the method (3), due to the limitation of the mother glass layout and the number of display panels, it is not always possible to arrange a region for a test sample.

Therefore, one aim of the present invention is to provide a display device in which a film thickness evaluation can be easily carried out. In addition, another aim of the present invention is to carry out an evaluation of a thin film sealed within a display region without damage. The display device related to one embodiment of the present invention is explained in detail below while referring to the diagrams.

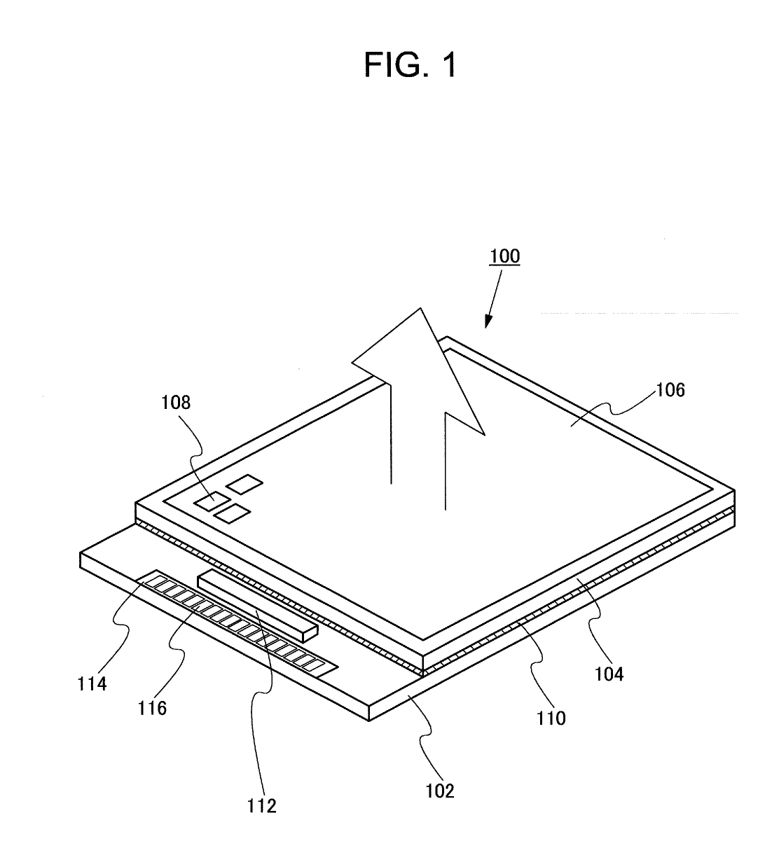

A structure of a display device 100 related to one embodiment of the present invention is shown in FIG. 1. The display device 100 is provided with a pixel region 106 in a first substrate 102. The pixel region 106 is arranging a plurality of pixels 108. A second substrate 104 is provided as a sealing member on an upper surface of the pixel region 106. The second substrate 104 is fixed to the first substrate 102 by a sealing member 110 which encloses the pixel region 106. The pixel region 106 provided over the first substrate 102 is sealed by the second substrate 104 as an encapsulant and the sealing member 110 so that it is not exposed to the air. Deterioration of an organic EL element provided in a pixel is suppressed by this sealing structure.

The first substrate 102 is provided with a terminal region 114 on one end part. The terminal region 114 is provided on the outer side of the second substrate 104. The terminal region 114 is formed by a plurality of connection terminals 116. A connection terminal 116 make a connection point between devices which output a video signal or a power source and a wiring substrate which connects the display panel. The connection point in the connection terminal 116 is exposed to the exterior. A driver circuit 112 which outputs a video signal input from the terminal region 114 to the pixel region 106 may also be provided in the first substrate 102.

In the case where the display device 100 is a top emission type, the light emitted from a pixel 108 is emitted after passing through the second substrate 104. As a result, the second substrate 104 includes transparency. Although not shown in the diagram, a color filter may also be provided in a region facing the pixel region 106 in the second substrate 104.

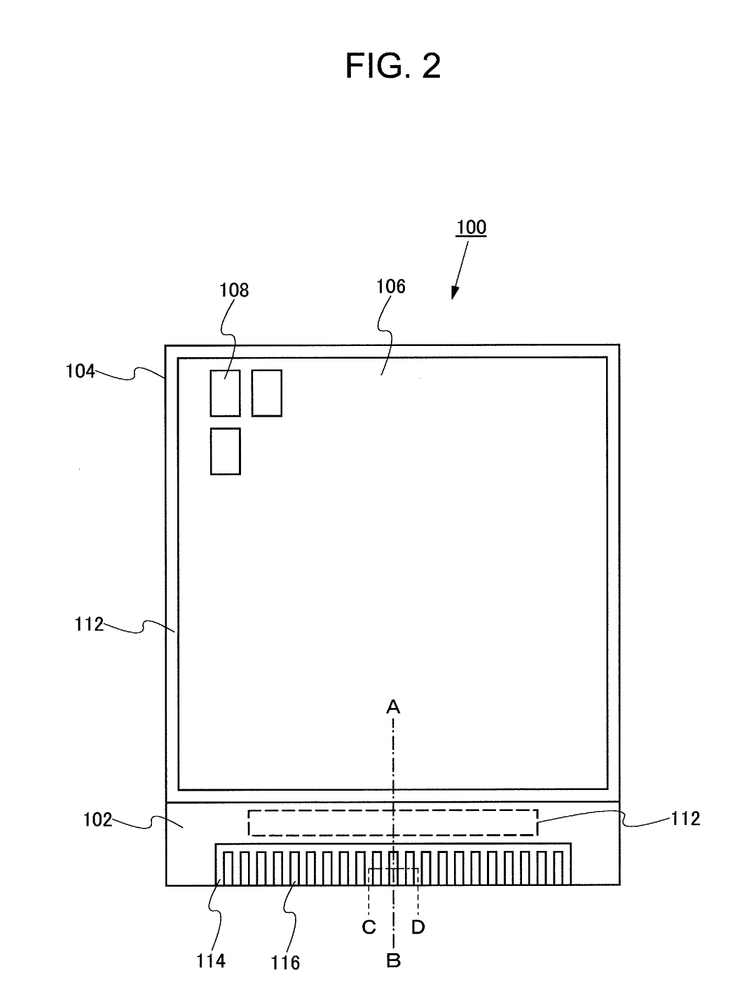

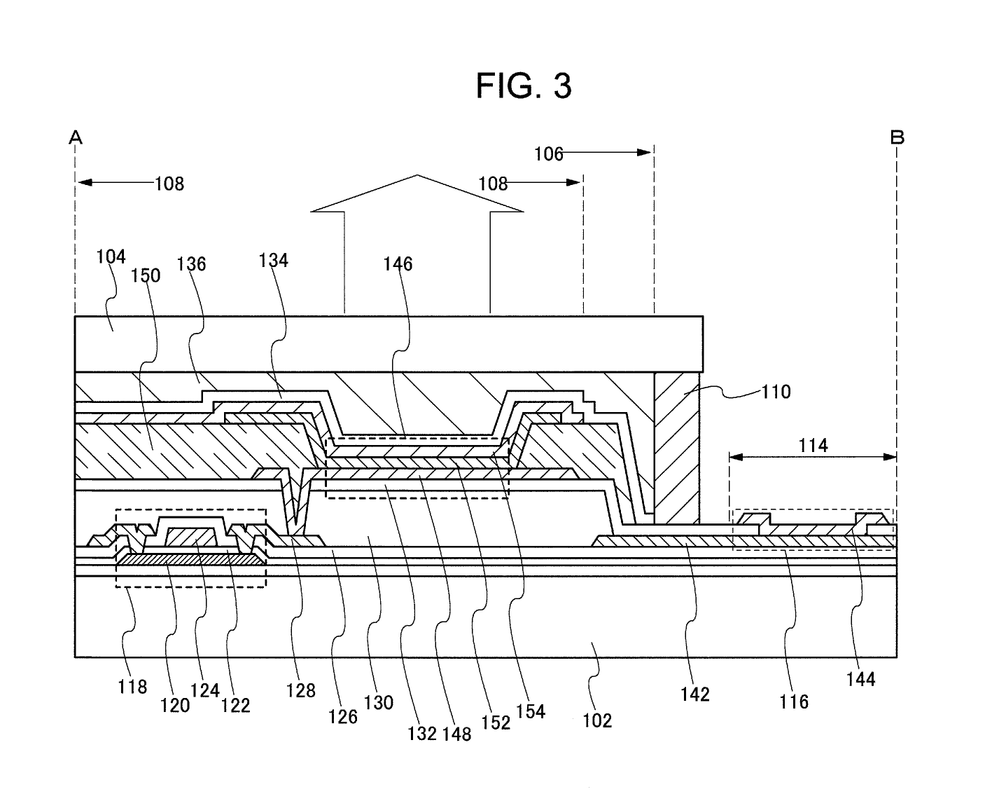

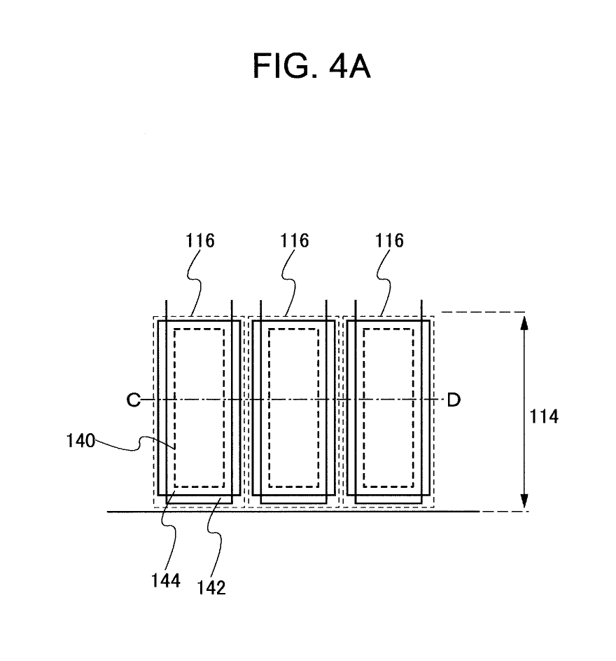

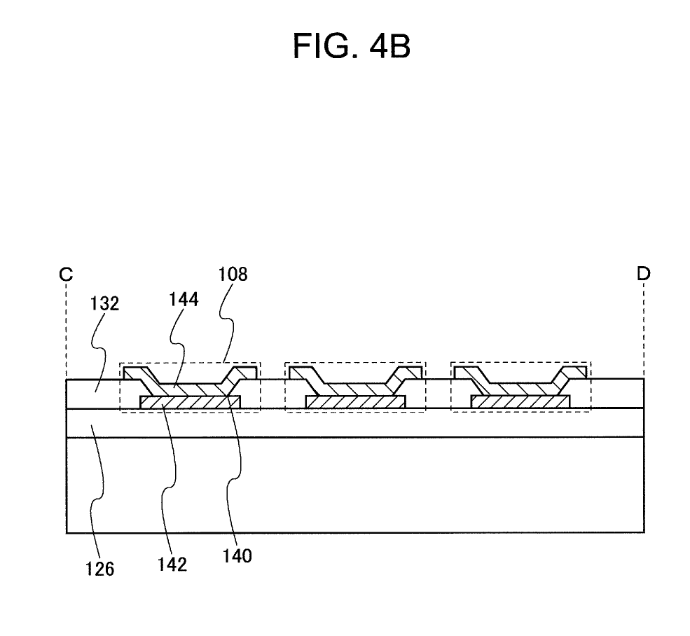

Details of the display device 100 exemplified in FIG. 1 are explained while referring to FIG. 2, FIG. 3, FIG. 4A and FIG. 4B. FIG. 2 shows a planar view of the display device 100. The pixel region 106 is formed by an arrangement of a plurality of pixels 108 and is provided in a region on the interior side encloses by the sealing member 110. A plurality of connection terminals 116 are provided in the terminal region 114. A cross-sectional structure corresponding to the line A-D shown in FIG. 2 is shown in FIG. 3. Furthermore, although the line A-B shown in FIG. 2 cuts through the pixel region 106, driver circuit 112 and terminal region 114, the cross-sectional structure shown in FIG. 3 may omit the driver circuit. In addition, details of the terminal region 114 shown in FIG. 2 are shown in FIG. 4A and a cross-sectional structure corresponding to the line C-D shown in FIG. 2 is shown in FIG. 4B.

FIG. 3 shows the aspect if the pixel region 106 and terminal region 114 provided above the first substrate 102. Although the pixel region 106 is formed from a plurality of pixels 108, in FIG. 3, an aspect are shown in which an organic EL element 146 and transistor 118 included in one pixel 108 are provided above the first substrate 102. The second substrate 104 is provided facing the pixel region 106 above the first substrate 102 and is fixed to the first substrate 102 using a sealing member 110. The pixel region 106 of the display device 100 is sealed by the second substrate 104 and sealing member 110, and includes a structure so that the organic EL element 146 and transistor 118 are not directly exposed to air. Furthermore, the first substrate 102 and second substrate 104 are fixed via a gap and a filler material 136 may be provided in the gap part.

The organic EL element 146 includes a structure in which a first electrode 148, organic EL layer 152 and second electrode 154 are stacked. In the present embodiment, the first electrode 148 of the organic EL element 146 is an anode and the second electrode 154 is an electrode corresponding to a cathode. In addition, because the display device 100 explained in the present embodiment is a top emission type, the first electrode 148 provided on a lower layer side of the organic EL layer 152 includes a light reflective surface, and the second electrode 154 having a transparency. The organic EL layer 152 includes an organic electroluminescence material and a structure in which a single layer or plurality of layers are stacked. One example of a stacked structure of the organic EL layer 152 is a structure in which the organic EL layer 12 is sandwiched by a hole injection layer and electrode injection layer. In addition, the stacked structure of the organic EL layer 152 may be appropriately inserted with a hole transport layer, an electron transport layer, hole block layer and electron block layer and the like.

In the case where the organic EL layer 152 is stacked with a hole injection layer, light emitting layer and electron injection layer in this order, the first electrode 148 is preferred to be formed using ITO (indium tin oxide) which has excellent hole injection properties. However, ITO which is used as the anode is a transparent conductive material and while it has a high transparency rate in the visible light range, it has very low reflective properties. As a result, a stacked structure of a transparent conductive film and light reflective film typified by ITO or IZO (indium zinc oxide) is applied in order to add a function to the first electrode 148 for reflecting light. The light reflective film is preferred to be formed using aluminum (Al) or silver (Ag) or an aluminum (Al) or silver (Ag) alloy material or compound material. For example, an allow material or compound material in which a few atomic percent of titanium (Ti) is added to aluminum (Al) may be used as the light reflective film. Since these metal materials have a high reflectance with respect to light in the visible light range, it is possible to increase the amount of reflected light output from the organic EL layer 152 to the first electrode 148 side. Furthermore, the light reflective film is not limited to these metals and apart from the metal materials mentioned above, titanium (Ti), nickel (Ni), molybdenum (Mo) or chrome (Cr) may also be used. In either case, by forming a structure in which the first electrode 148 is a conductive film using a transparent conductive layer and a light reflective layer, it is possible to add a light reflective electrode function while maintaining the function of an anode.

The second electrode 154 provided on the upper surface side of the organic EL layer 152 have transparency and is required to have excellent electron injection properties as a cathode. As a result, the second electrode 154 is formed using a conductive material including an alkali metal or alkali earth metal. For example, aluminum including lithium or magnesium is used as the material of the second electrode 154. In this case, in order to provide the second electrode 154 with transparency, a cover film formed from aluminum including lithium or magnesium is required to have a thickness to the extent that allows light to pass through. In addition, as an alternative form, a layer including an alkali metal or alkali earth metal may be provided between the second electrode 154 and organic EL layer 152 (electron injection layer). In this case, as long as it includes transparency, the number of materials that can be selected for forming the second electrode 154 can be increased, for example it is possible to use a transparent conductive material such as ITO or IZO.

Furthermore, the periphery edge part of the first electrode 148 may be covered by a bank layer 150. The organic EL layer 152 and second electrode 154 are provided along the surface of the bank layer 150 from the upper surface of the first electrode 148. By covering the periphery edge part of the first electrode 148 using the bank layer 150, the second electrode 154 is prevented from shorting by a step part formed by the first electrode 148.

As described above, light emitted from the organic EL layer 152 is output to the second substrate 104 by combining the first electrode 148 provided with light reflecting properties and the second electrode 154 provided with transparency. That is, emission from the organic EL element 146 forming a pixel 108 is output through the second substrate 104. Furthermore, a fourth insulation layer 143 may be provided on an upper layer side of the second electrode 154 as a transparent passivation (layer) in order to protect the organic EL element 146.

The transistor 118 is including a semiconductor layer 120, a gate insulation layer 122 covering the semiconductor layer 120, and a gate electrode 124 provided so as to overlap the semiconductor layer 120 on an upper surface of the gate insulation layer 122. The semiconductor layer 120 is formed using amorphous or polycrystalline silicon or an oxide semiconductor. A channel region is formed in the semiconductor layer 120 when the transistor 118 applies a gate voltage to the gate electrode 124. The semiconductor layer 120 further includes a region corresponding to a source and drain of a transistor. A source/drain electrode 129 provided above the first insulation later 126 is in contact with a region corresponding to a source region and drain region of the semiconductor layer 120.

The source/drain electrode 128 is formed using a conductive layer. The conductive layer is formed from a metal material such as aluminum (Al) and the like. This conductive layer may also include a stacked structure of aluminum (Al) and a metal layer with a high melting point such as titanium (Ti), molybdenum (Mo) or tantalum (Ta). By providing the source/drain electrode 128 with this type of stacked structure, it is possible to increase thermal resistance and form a good ohmic contact with the semiconductor layer 120.

An insulation layer is provided between the transistor 118 and the organic EL element 146. The insulation layer may be formed from a plurality of layers. A form is shown in FIG. 3 in which a second insulation layer 130 and third insulation layer 132 are provided as the insulation layer. At this time, the second insulation layer 130 may be buried with the transistor 118 and include a function as a leveling layer for flattening a surface. In addition, the third insulation layer 132 may include the function of a passivation layer for protecting the transistor 118. The first electrode 148 of the organic EL element 146 is connected with the source/drain electrode 128 via a contact hole which passes through the second insulation layer 130 and third insulation layer 132.

The connection terminal 116 is provided in a terminal region 114 provided at an end part of the first substrate 102. The connection terminal 116 is formed at one end of the first wiring layer 142 extending from the pixel region 106. A second wiring layer 144 which covers the upper surface of the first wiring layer 142 is provided at the connection terminal 116.

The first wiring layer 142 is formed using the same conductive layer as the gate electrode 124 forming the transistor 118, or the same conductive layer as a layer which forms the source/drain electrode 128. By forming the first wiring layer 142 extending to the connection terminal 116 using any one of these conductive layers, it is possible to reduce the manufacturing process. An aspect whereby the first wiring layer 142 is formed using a conductive layer which forms the source/drain electrode 128 is shown in FIG. 3.

Since the second insulation layer 130 and third insulation layer 132 are formed in an upper layer of the first wiring layer 142, these insulation layers are removed in the terminal region 114. In this case, since the second insulation layer 130 which is used as a leveling layer is a thick film, almost or all of the insulation layer is removed so that the connection terminal 116 is exposed in the terminal region 114. On the other hand, since the third insulation layer 132 is a passivation layer of the transistor 118, it also functions as a passivation layer of the first wiring layer 142. As is shown in FIG. 4A and FIG. 4B, the third insulation layer 132 covers a side surface part and upper surface part of the first wiring layer 142, an aperture part 140 is provided in the terminal region 114 so that the first wiring layer 142 is exposed.

The second wiring layer 144 is provided overlapping the aperture part 140 of the third insulation layer 132. That is, the second wiring layer 144 is in contact with and electrically connected with the first wiring layer 142 in the aperture part 140. The second wiring layer 144 may be formed using a conductive layer formed on an upper layer side of the third insulation layer 132. In this case, by forming the second wiring layer 144 using a conductive layer which forms the first electrode 148, it is possible to provide the structure of the first electrode 148 in the terminal region 114. In this way, it is possible to arrange the structure of the first electrode 148 which becomes sealed by the second substrate 104 and sealing member 110 on the outer side of the pixel region 106.

In the present embodiment, since the first electrode 148 includes a stacked structure of a transparent conductive film of ITO or IZO and a metal film formed from aluminum (Al) or silver (Ag), the second wiring layer 144 also includes the same stacked structure. Since the transparent conductive layer of ITO or IZO is a hard conductive layer compared to aluminum (Al), it is possible to use the layer as a protection film of the first wiring layer 142.

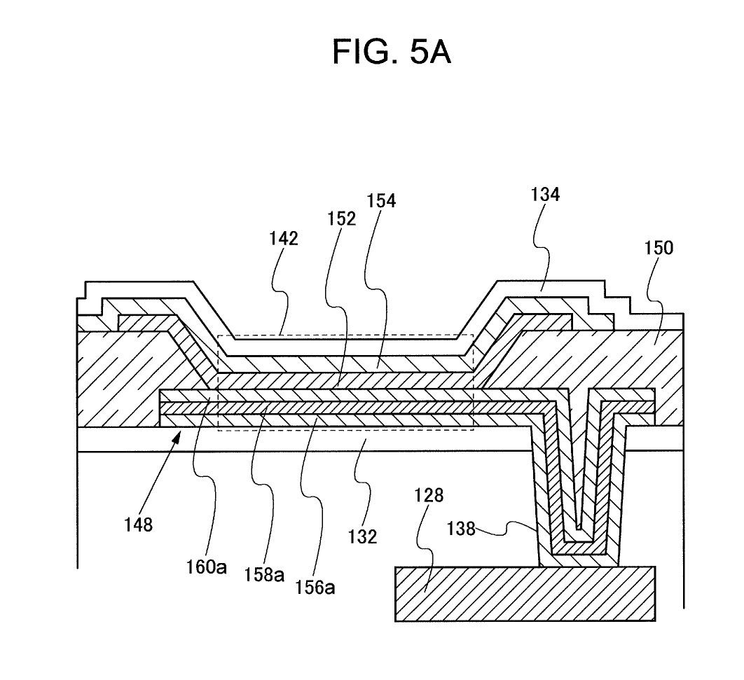

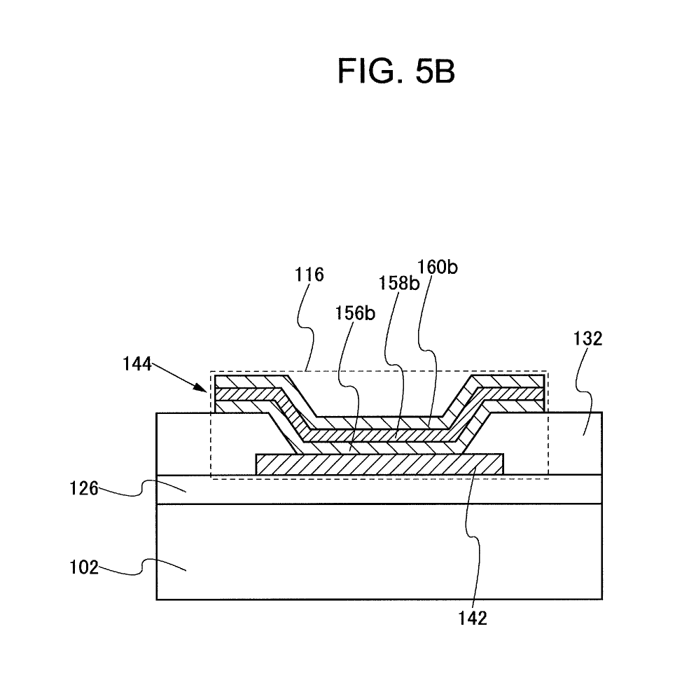

Details of the first electrode 148 provided in a pixel 108 and the second wiring layer 144 provided in the terminal region 114 are shown in FIG. 5A and FIG. 5B. The first electrode 148 includes a structure in which a first conductive layer 156a, second conductive layer 158a and third conductive layer 160a are stacked in order from the bottom layer side. Among these, the third conductive layer 160a on the uppermost layer is formed using a transparent conductive material such as ITO or IZO in order to realize the function of an anode. The second conductive layer 158a on a lower layer of the third conductive layer 160a is formed using a metal material such as aluminum (Al) or silver (Ag) in order to form a light reflective surface. In addition, the first conductive layer 156a is formed using an appropriate conductive material in order to increase adhesion between the source/drain electrode 128 and first wiring layer 142 and to reduce contact resistance. At the same time, in the case where adhesion between the second conductive layer 158 and the third insulation layer 132 is poor, the first conductive layer 156 includes a function to compensate for adhesiveness. For example, it is possible to form the first conductive layer 156a using a transparent conductive material such as ITO or IZO. In addition, it is also possible to form the first conductive layer 156a using a metal material such as titanium (Ti) or titanium nitride (TiN) or an alloy of molybdenum (Mo) and tungsten (W).

The first electrode 148 includes a function for reflecting light emitted from the organic EL element 146 using a light reflecting surface of the second conductive layer 158. Light emitted from the organic EL layer enters the third conductive layer 160a and becomes a light path for light reflected by the light reflecting surface of the second conductive layer 158 to pass through. That is, since the third conductive layer 160a becomes a light path of incident light and reflected light, control of film thickness is important for determining a light path length. The third conductive layer 160a is preferred to be formed to a thickness of 500 nm or less, and preferably from 5 nm to 200 nm, 100 nm for example. When the third conductive layer 160a is formed thicker than this range, the emitting intensity of the organic EL element 146 become reduced due to a loss in light adsorption, and when the layer is formed thinner than this range, it is becomes difficult to control film thickness during manufacture.

When the film thickness of the third conductive layer 160a is varied for each panel and/or each manufacturing lot, the amount of light emitted from a pixel changes due to the influence of light interference effects. In addition, light intensity of each color R (red), G (green) and B (blue) output from a pixel changes leading to a change in color tone. As a result, inspecting the film thickness of the third conductive layer 160a in a manufactured panel is an extremely important element for process management and product quality management.

In the display device related to the present embodiment, the same structure as the first electrode 148 is provided in a state where the second wiring layer 144 is exposed in the terminal region 114 which is an end part of the first substrate 102. As is shown in FIG. 5B, the second wiring layer 144 includes a stacked structure of the first conductive layer 156b, second conductive layer 158b and third conductive layer 160b the same as the first electrode 148.

In the present embodiment, evaluation of the film thickness of the first electrode 148 can be performed by measuring the film thickness of the third conductive layer 160b of the second wiring layer 144 exposed to the exterior. In this way, it is possible to known the thickness of the third conductive layer 160a of the first electrode 148 which becomes sealed within a panel. Since the third conductive layer 160b is provided on an upper surface of the second conductive layer 158b which forms a light reflecting surface, it is possible to optically measure the film thickness of the third conductive layer 160b using an ellipsometer. In addition, it is possible to evaluate the film thickness of the third conductive layer 160b using a fluorescent X-ray film thickness meter.

In addition, since the first conductive layer 156b in the second wiring layer 144 has the same material as the first conductive layer 156a of the first electrode 148, it is possible to increase adhesion with the first wiring layer 142 and reduce contact resistance.

According to the display device related to the present embodiment, by providing the second wiring layer 144 provided in the terminal region 114 with substantially the same laminated structure as the first electrode 148 provided in the pixel region 106, it is possible to substitute by evaluating the film thickness of the second wiring layer 144 when wishing to evaluate the film thickness of the first electrode 148. In this way, it is possible manage the film thickness of the first electrode with non-destructive.

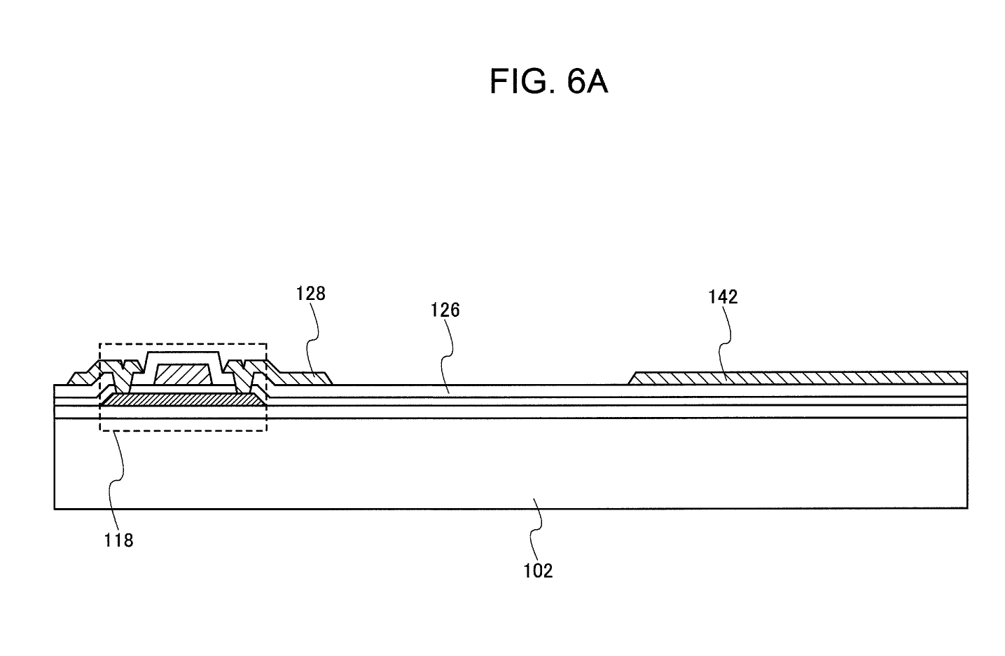

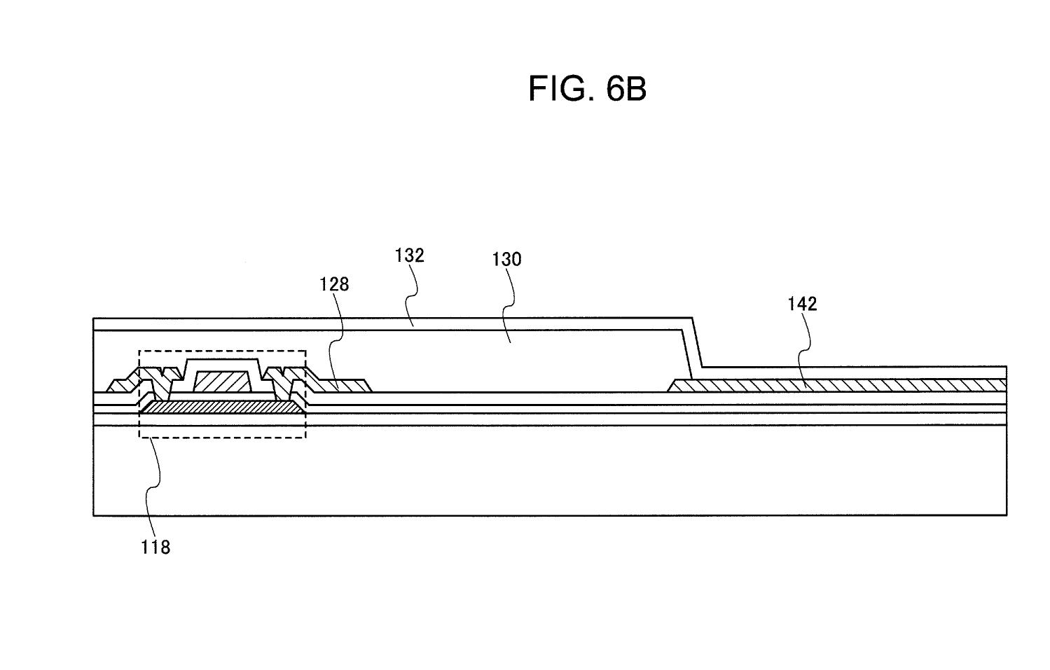

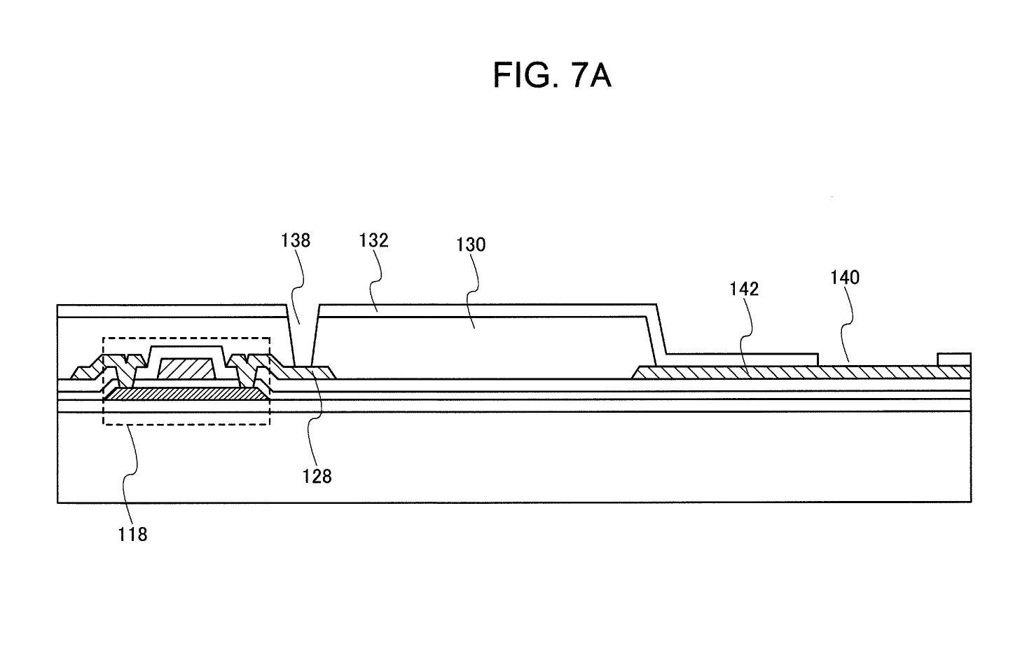

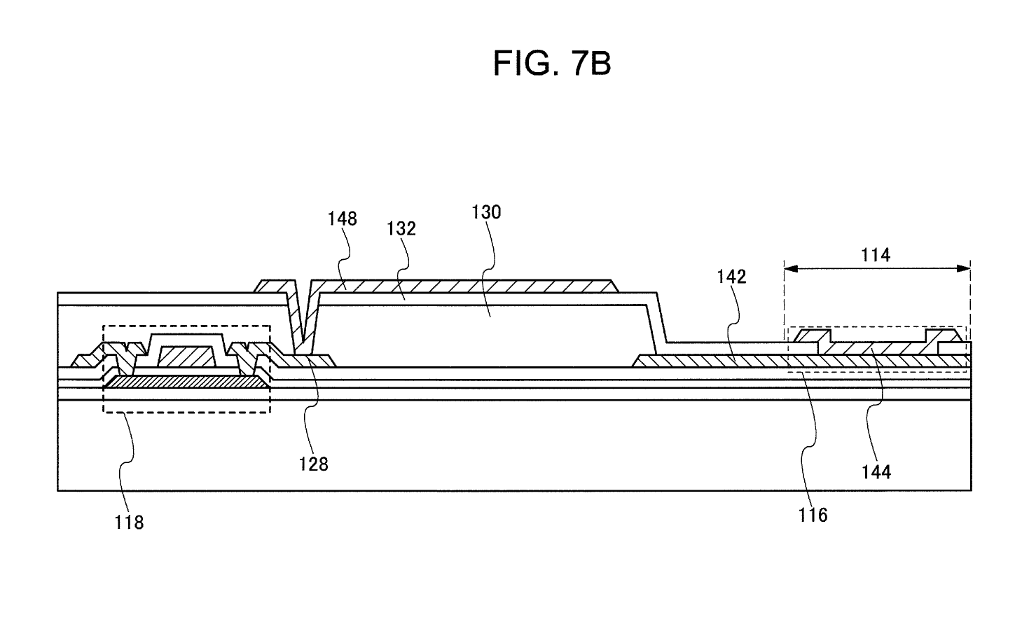

Next, an example of a manufacturing method of the display device related to the present embodiment is shown is explained. FIG. 6A and FIG. 6B and FIG. 7A and FIG. 7B shows cross-sections for explaining a manufacturing process of the display device 100 related to the present embodiment. FIG. 6A shows a step for forming a source/drain electrode 128 on an upper surface of the first insulation layer 126 and the first wiring layer 142 extending to the terminal region 114. In this step, after forming a contact hole which passes through the first insulation layer 126 and gate insulation layer 122, a conductive layer is forming above the first insulation layer 126. The conductive layer is formed from a single layer of aluminum (Al) or aluminum alloy with a high melting point metal element such as titanium (Ti) added to aluminum (Al), or a stacked layer with the first conductive layer formed from titanium (Ti), molybdenum (Mo) or molybdenum tungsten alloy and a second conductive layer formed from aluminum or aluminum alloy. The source/drain electrode 128 is formed by patterning the conductive layer. The first wiring layer 142 is formed extending to the terminal region 114 using the same conductive layer.

FIG. 6B shows a step for forming the second insulation layer 130 and third insulation layer 132. The second insulation layer 130 is formed using an organic resin material with insulation properties. A polyimide resin or acrylic resin is used as the organic resin material. The second insulation layer 130 is formed by coating the organic resin material on an upper surface of the first substrate 102 and sintered at a predetermined temperature. The organic resin material is formed to a thickness from 500 nm to 5000 nm, for example 1500 nm as the second insulation layer 130. By coating the organic resin layer used as the second insulation layer 130 to this film thickness, the transistor 118 and first wiring layer 142 are buried in the organic resin layer. Since the first wiring layer 142 is exposed in the terminal region, it is necessary to remove the organic resin layer in the terminal region 114 using etching. The surface of the second insulation layer 130 formed in this way is flattened by a leveling effect when forming the organic resin layer. In addition, removal is performed so that the second insulation layer 130 does not exist in the terminal region 114.

The third insulation layer 132 is formed using an inorganic insulation material. Silicon nitride is preferably used as the inorganic insulation material and silicon oxynitride and silicon nitride may also be used. The third insulation layer 132 is formed so as to cover the second insulation layer 130 and the terminal region 114. The third insulation layer 132 is preferred to be formed to a thickness from 100 nm to 500 nm. By forming the third insulation layer 132 with this film thickness, it is possible to provide a function of a passivation layer for blocking water vapor and the like.

FIG. 7A shows a step for forming a contact hole in the pixel region 106 and for forming an aperture part which exposes the first wiring layer 142 in the terminal region 114. The contact hole 138 is formed by etching the third insulation layer 132 and second insulation layer 130 to expose the source/drain electrode 128 of the transistor 118. The aperture part 140 is formed by etching the third insulation layer 132 so as to expose the upper surface of the first wiring layer 142. The contact hole 138 and aperture part 140 can be formed by dry etching.

FIG. 7B shows a step for forming the first electrode 148 in the pixel region 106 and for forming the second wiring layer 144 in the terminal region 114. The first electrode 148 and second wiring layer 144 are formed using the same conductive layer. The conductive layer is formed by stacking the first conductive layer, second conductive layer and third conductive layer as mentioned previously. The first conductive layer is formed using a transparent conductive material such as ITO or IZO or a metal such as titanium (Ti) or titanium nitride (TiN) or a metal alloy such as molybdenum (Mo) and tungsten (W). The second conductive layer is formed using a metal material such as aluminum (Al) or silver (Ag) for forming a light reflecting surface. In the case where the display device is a top emission type, the film thickness of the second conductive layer is a first a thickness whereby it is possible to form a reflective surface which sufficiently suppresses transparent light and when sufficient low resistance and processing when patterning is considered, the film thickness is preferred to be from 50 nm to 200 nm, for example 130 nm. The third conductive layer is formed using a transparent conductive material such as ITO or IZO to a thickness of 500 nm or less, preferably from 50 nm to 200 nm, for example 10 nm.

It is possible to form the first to third conductive layers using a sputtering method. The first electrode 148 and second wiring layer 144 are formed by etching the conductive layers formed on the entire surface of the first substrate 102. Since the first electrode 148 and second wiring layer 144 are formed from the same conductive layer, it is possible to form these at the same time by etching.

Following this, the organic EL layer 152, second electrode 154 and fourth insulation layer 134 are formed in order and by binding the second substrate 104 using the sealing member 110, it is possible to manufacture the display device 100 shown in FIG. 3.

According to the manufacturing method of the display device related to the present embodiment, it is possible to form the first electrode 148 provided in the pixel region 106 and the second wiring layer 144 provided in the terminal region 114 at the same time. It is possible to manufacture the first electrode 148 and second wiring layer 144 using the same conductive layer. The first conductive layer 156 and the second wiring layer 144 have the same stacked structure. As a result, it is possible to substitute by evaluating the film thickness of the second wiring layer 144 when wishing to evaluate the film thickness of the first electrode 148.

For example, in the case where the first electrode 148 includes a stacked structure of the first conductive layer, second conductive layer and third conductive layer, if the film thickness of the third conductive layer of the second wiring layer 144 is measured, it is possible to indirectly know the film thickness of the third conductive layer in the first electrode 148 when desiring to evaluate the film thickness of the third conductive layer. That is, according to the manufacturing method related to the present embodiment, in the step after the manufacturing process of the display device is completed, it is possible to evaluate the film thickness of the first electrode 149 sealed within a panel by evaluating the film thickness of the second wiring layer 144.

According to another embodiment of the present invention, as described above, by forming the first electrode 148 in the pixel region 106 and the second conductive layer 158 in the terminal region 114 using substantially the same laminated structure, it is possible to inspect the film thickness of the first electrode 148. That is, it is possible to perform an inspection by substituting the film thickness of the third conductive layer 160b of the second conductive layer 158 having substantially the same laminated structure in order to inspect the film thickness of the third conductive layer 160a in the first electrode 148. In this way, it is possible to inspect an electrode component which affects the optical properties of a display device without damaging the device.

Furthermore, although the present embodiment exemplified a top emission type display device, the present invention is not limited to this and can be applied to a bottom emission type display device. A bottom emission type display device is formed using a transparent conductive material in order to provide a first electrode provided in a pixel with transparency. According to the present embodiment, a first electrode in a pixel and a second conductive layer which forms a connection terminal in a terminal region are formed using substantially the same laminated structure. As a result, if the film thickness of the second conductive layer is measured, it is possible to evaluate the film thickness of the first electrode. Since the light which is emitted by an organic EL layer in a bottom emission type display device is output after passing through a first electrode, it is possible to manage output light intensity and color tone of emitted light by evaluating the film thickness of a first electrode.

What is claimed is:

1. A display device comprising:
a pixel region provided with a plurality of pixels, and a terminal region provided on an outer side of the pixel region;
each of the plurality of pixels including a first electrode, an organic layer including a light emitting layer above the first electrode, and a second electrode having a transparency above the organic layer;
the terminal region including a first wiring layer and a second wiring layer above the first wiring layer; and
the first electrode and the second wiring layer having a same laminated structure.

2. The display device according to claims 1, wherein the first electrode and the second wiring layer having a laminated structure of at least two conductive layers, the two conductive layers including a first conductive layer and a second conductive layer, the first conductive layer is a light reflecting metal layer and the second conductive layer is a transparent conductive layer stacked above the first conductive layer.

3. The display device according to claim 2, wherein the metal layer is a selected from aluminum (Al) or silver (Ag), or an alloy material of aluminum (Al) or silver (Ag).

4. The display device according to claim 2, wherein the transparent conductive layer is an indium tin oxide layer (ITO) or an indium zinc oxide layer (IZO).

5. The display device according to claim 1, wherein a periphery of the pixel region is sealed by a sealing member and the terminal region is provided on an outer side of the sealing member.

6. The display device according to claim 1, wherein an upper surface of the pixel region is covered by a filler material and the terminal region is provided on an outer side of the filler material.

7. A manufacturing method of a display device including a pixel region provided with a plurality of pixels, and a terminal region provided on an outer side of the pixel region, the method comprising:
forming a first electrode including a light reflecting surface, an organic layer including a light emitting layer above the first electrode, and a second electrode having a transparency above the organic layer in a display region;
forming a first wiring layer and second wiring layer above the first wiring layer in the terminal region; and
forming the first electrode and the second wiring layer simultaneously.

8. The manufacturing method of a display device according to claim 7, wherein the first electrode and the second wiring layer are laminated with at least two conductive layers, a first conductive layer of the two conductive layers is formed from a light reflecting metal layer and a second conductive layer of the two conductive layers is formed from a transparent conductive layer stacked above the first conductive layer.

9. The manufacturing method of a display device according to claim 8, wherein material of the metal layer is a selected from aluminum (Al) or silver (Ag), or an alloy material of aluminum (Al) or silver (Ag).

10. The manufacturing method of a display device according to claim 8, wherein the transparent conductive layer is an indium tin oxide layer (ITO) or an indium zinc oxide layer (IZO).

11. The manufacturing method of a display device according to claim 7, wherein the first electrode and the second wiring layer are formed by etching the at least two conductive layers simultaneously.

12. An inspection method of a display device including a pixel region provided with a plurality of pixels, and a terminal region provided on an outer side of the pixel region, the method comprising:
each of the plurality of pixels including a first electrode, an organic layer including a light emitting layer provided above the first electrode, and a second electrode having a transparency above the organic layer;
the terminal region including a first wiring layer and a second wiring layer above the first wiring layer;
the first electrode and the second wiring layer having a same laminated structure; and
an inspection of the first electrode is performed using a film thickness of the second wiring layer as an alternative characteristic.

13. The inspection method of a display device according to claim 12, wherein the first electrode and the second wiring layer have a structure stacked with at least two conductive layers, a first layer of one of the two conductive layers is formed using a light reflecting metal layer and a second layer is formed using a transparent conductive layer stacked above the first layer.

14. The inspection method of a display device according to claim 13, wherein the transparent conductive layer is an indium tin oxide layer (ITO) or an indium zinc oxide layer (IZO).

15. The inspection method of a display device according to claim 12, wherein a periphery of the pixel region is sealed by a sealing member and the terminal region is provided on an outer side of the sealing member.

16. The inspection method of a display device according to claim 12, wherein an upper surface of the pixel region is covered by a filler material and the terminal region is provided on an outer side of the filler material.
